(19) United States
(12) Patent Application Publication
(10) Pub. No.: US 2026/0247910 A1
(43) Pub. Date: Aug. 20, 2026

(54) Wafer position detection device and semiconductor equipment

(71) Applicant: BEIJING NAURA MICROELECTRONICS EQUIPMENT CO., LTD., Beijing (CN)

(72) Inventors: Haiyang ZHAO, Beijing (CN); Lulu CHEN, Beijing (CN)

(73) Assignee: BEIJING NAURA MICROELECTRONICS EQUIPMENT CO., LTD., Beijing (CN)

(21) Appl. No.: 19/480,385

(22) PCT Filed: Jun. 12, 2024
(86) PCT No.: PCT/CN2024/098561

§ 371 Date: Oct. 31, 2025

(30) Foreign Application Priority Data
Jun. 13, 2023 (CN) 202310701127.5

(51) Int. Cl. H10P 72/00; G01B 11/03; H10P 72/50

(52) U.S. Cl. CPC H10P 72/0606; G01B 11/03; H10P 72/53; G01B 2210/56

(57) ABSTRACT

A wafer position detection device and semiconductor equipment are disclosed. The device contains a linear sensor transmitter emitting a linear beam. The linear sensor transmitter slides on an annular sliding rail above the chamber and a linear sensor receiver slides on another annular sliding rail below the chamber. The orthogonal projection of the transmitter toward the wafer and an orthogonal projection of the receiver toward the wafer overlap partially on the wafer. A processor controls a driver to drive the linear sensor transmitter and receiver to slide synchronously along respective annular sliding rails, controls the linear sensor transmitter to emit detection signals and the linear sensor receiver to receive detection signals unobstructed by the wafer, and determines a center position of the wafer based on the detection signals received by the linear sensor receiver. The semiconductor chamber has windows transparent to the detection signals.

### FIELD OF THE INVENTION

The present disclosure relates to the field of semiconductor manufacturing technology, specifically to a wafer position detection device and semiconductor equipment.

### BACKGROUND OF THE INVENTION

Before transfer, wafers need to be calibrated first, for example, centering calibration, to prevent excessive wafer misalignment which could cause the robotic arm to fail to pick them up. Prior to calibration, the wafer's position needs to be detected.

Currently, an existing wafer position detection method suffers from difficulties in process chamber sealing and requires a cooling system.

### SUMMARY OF THE INVENTION

The present disclosure provides a wafer position detection device and semiconductor equipment that can improve process chamber sealing and cooling system.

A first aspect of the present disclosure provides a wafer position detection device, applied to a semiconductor chamber, wherein the wafer position detection device includes: a first annular sliding rail, a second annular sliding rail, a linear sensor transmitter, a linear sensor receiver, a driver, and a processor; wherein the semiconductor chamber is provided with a supporting portion for carrying a wafer; wherein the wafer position detection device is disposed outside the semiconductor chamber.

Herein the first annular sliding rail and the second annular sliding rail are oppositely arranged on upper and lower sides of the semiconductor chamber;
the linear sensor transmitter is connected to the first annular sliding rail with a sliding mechanism, and the linear sensor receiver is connected to the second annular sliding rail also with a sliding mechanism; an orthogonal projection of the linear sensor transmitter toward the wafer and an orthogonal projection of the linear sensor receiver toward the wafer overlap with each other partially on the wafer;
the driver is configured to drive the linear sensor transmitter and the linear sensor receiver to slide along their respective annular sliding rails;
the processor is configured to perform steps of: S110, control the driver to drive the linear sensor transmitter and the linear sensor receiver to slide synchronously along their respective annular sliding rails; S120, control the linear sensor transmitter to emit detection signals and the linear sensor receiver to receive unobstructed detection signals from the wafer; S130, determine an estimated center position of the wafer based on the detection signals received by the linear sensor receiver, wherein the detection signals are able to penetrate the windows of the semiconductor chamber.

As an example, S130 includes:
S131, determining a contour of the wafer based on the detection signals received by the linear sensor receiver; and
S132, selecting at least three positional points on the contour, and calculating the center position of the wafer based on the at least three positional points.

As an example, an orientation feature (notch) is provided on an edge of the wafer, and the orientation-feature-central angle spanned over the orientation feature is θ₀; S132 comprises:
S1321, selecting three first positional points on the contour, and calculating a first center position of the wafer based on the three first positional points, wherein a first central angle between any two adjacent first positional points among the three first positional points is 120°;
S1322, selecting three second positional points on the contour, and calculating a second center position of the wafer, wherein the three second positional points correspond one-to-one with the three first positional points, and a second central angle between each second positional point and its corresponding first positional point is equal to a first preset angle θ₁, and θ₀≤θ₁≤120°−θ₀;
S1323, selecting three third positional points on the contour, and calculating a third center position of the wafer, wherein the three third positional points correspond one-to-one with the three first positional points, and the third central angle between each third positional point and its corresponding first positional point is equal to a second preset angle θ₂, θ₀<θ₂≤120°−θ₀, and °₁≠θ₂; and
S1324, calculating the estimated center position of the wafer by averaging two closest positions among the first center position, the second center position, and the third center position of the wafer.

As an example, an orientation feature is provided on an edge of the wafer, and the processor is further configured to:
S133, calculate an azimuth angle of the orientation feature relative to the estimated center position of the wafer.

As an example, S133 includes:
S1331, determining an ideal circle based on the estimated center position of the wafer and a radius of the wafer;
S1332, comparing the ideal circle to the contour of the wafer to determine a starting position and an ending position of the orientation feature;
S1333, calculating an azimuth angle θ_{S} of the starting position relative to the estimated center position of the wafer, and an azimuth angle θ_{F} of the ending position relative to the estimated center position of the wafer; and
S1334, calculating an azimuth angle θ_{M} of a midpoint of a line connecting the starting position and the ending position, relative to the estimated center position of the wafer.

As an example, the processor is further configured to compare the estimated center position of the wafer with a pre-stored target position, and determine an offset between the estimated center position of the wafer and the target position.

As an example, controlling the linear sensor receiver to receive the detection signals unobstructed by the wafer includes:
controlling the linear sensor to perform a detection signal reception each time it moves a predetermined small distance as the arc length, wherein the predetermined arc length is less than a predetermined calibration accuracy.

As an example, the linear sensor transmitter extends along a radius of the first annular sliding rail, and the linear sensor transmitter comprises signal emitting spots spaced apart spaced apart by a predetermined distance.

The linear sensor receiver extends along a radius of the second annular sliding rail, and the linear sensor receiver comprises signal receiving spots spaced apart by the predetermined distance, wherein the signal receiving spots align one-to-one with the signal emitting spots, wherein the predetermined distance is less than the predetermined calibration accuracy.

As an example, the linear sensor transmitter comprises a line of light emitters; the linear sensor receiver comprises a light detector.

A second aspect of the present disclosure provides a semiconductor equipment, including a semiconductor chamber, a wafer transfer device, and a wafer position detection device described above.

The wafer position detection device is configured to detect a position of a wafer located within the semiconductor chamber.

The wafer transfer device is configured to transfer the wafer and perform position correction on the wafer based on detection results from the wafer position detection device.

As described above, the wafer position detection device comprises a linear sensor transmitter and a linear sensor receiver, forming a pair of opposing sensors positioned on opposite sides of the wafer-above and below. The projection of the linear sensor transmitter onto the wafer, and the projection of the linear sensor receiver onto the wafer, partially overlap with each other. This allows for the identification of the wafer's edge. The processor controls the driver to synchronously slide the linear sensor transmitter and the linear sensor receiver along their respective annular rails, enabling a scan of the entire wafer circumference to determine the center position of the wafer. The presently disclosed wafer position detection device avoids the need for sealing any connection between the semiconductor chamber and a rotation shaft, because wafers inside the semiconductor chamber are fixed and stationary, unlike in the case of the problematic existing detection devices. The components in the semiconductor chamber do not include any motor, so a cooling system becomes unnecessary, even when used for high-temperature wafer handling. This simplifies the system and reduces maintenance difficulty.

### BRIEF DESCRIPTION OF DRAWINGS

The drawings herein are incorporated in and constitute a part of this specification, illustrating embodiments consistent with the present disclosure and, together with the specification, serve to explain the principles of the present disclosure. In order to more clearly illustrate the technical solutions in embodiments of the present disclosure, the following is a brief description of the accompanying drawings to be used in the description of the embodiments, it is obvious that for a person of ordinary skill in the art, without creative work, other drawings can be obtained according to these accompanying drawings.

FIG. 1 is a structural schematic diagram of a wafer position detection device in the related art.

FIG. 2 is a structural schematic diagram of a wafer position detection device according to an embodiment of the present disclosure.

FIG. 3 is a structural schematic diagram of a control system of a wafer position detection device according to an embodiment of the present disclosure.

FIG. 4 is a control flow method of a processor according to an embodiment of the present disclosure.

FIG. 5 is a flowchart illustrating a method for determining the center position of a wafer according to an embodiment of the present disclosure.

FIG. 6 is a schematic diagram illustrating projections of a linear sensor transmitter and a linear sensor receiver onto a wafer according to an embodiment of the present disclosure.

FIG. 7 is a flowchart illustrating a preferred method for calculating the center position of a wafer according to an embodiment of the present disclosure.

FIG. 8 is a schematic diagram illustrating the selection of three position points on a contour of a wafer according to an embodiment of the present disclosure.

FIG. 9 is a schematic diagram illustrating the detection of an azimuth angle of an orientation feature on a wafer according to an embodiment of the present disclosure.

FIG. 10 is a flowchart illustrating a process for calculating the azimuth angle of the orientation feature relative to the center position of the wafer according to an embodiment of the present disclosure.

FIG. 11 is a schematic diagram of an application scenario of a semiconductor device according to an embodiment of the present disclosure.

The realization, functional characteristics, and advantages of the present disclosure will be further explained in conjunction with the embodiments, referencing the drawings. The specific embodiments of the present disclosure are illustrated through the aforementioned drawings, and a more detailed description will follow.

These drawings and textual descriptions are not intended to limit the scope of the inventive concept of the present disclosure in any way, but rather to illustrate the concept of the present disclosure to those skilled in the art by referencing specific embodiments.

### DETAILED DESCRIPTION

A detailed description of exemplary embodiments will now be given, with examples illustrated in the accompanying drawings. In the following description, unless explicitly stated otherwise, the same numerals in different drawings represent the same or similar elements. The implementations described in the following exemplary embodiments do not represent all implementations consistent with the present application. Rather, they are merely examples of devices and methods consistent with some aspects of the present disclosure, as detailed in the appended claims.

It should be noted that, throughout this document, the terms “comprising,” “including,” or any other variation thereof are intended to cover non-exclusive inclusions, allowing a process, method, article, or apparatus that includes a series of elements to include not only those elements but also other elements not explicitly listed, or elements inherent to that process, method, article, or apparatus. Unless further restricted, a statement “including a . . . ” element does not exclude the presence of additional identical elements in the process, method, article, or apparatus. Furthermore, components, features, or elements with the same name in different embodiments of the application may have the same meaning or different meanings, and their specific meaning should be determined based on the context of the specific embodiment.

It should be further understood that the terms “include” and “comprise” indicate the existence of the described features, steps, operations, elements, components, items, categories, and/or groups, but do not exclude the existence, presence, or addition of one or more other features, steps, operations, elements, components, items, categories, and/or groups. The terms such as “or,” “and/or,” and “including at least one of the following,” are to be interpreted inclusively, or as meaning any one or any combination. For example, “including at least one of: A, B, C” means “any one of the following: A; B; C; A and B; A and C; B and C; A, B, and C. Also, “A, B or C” or “A, B and/or C” means “any of the following: B; C; A and B; A and C; B and C; A, B, and C. Exceptions to this definition apply only when combinations of elements, functions, steps, or operations are inherently paradoxical in some way.

It should be understood that while terms like “first,” “second,” and “third” may be used to describe various pieces of information within this document, this information should not be limited by these terms. These terms are used solely to distinguish between information of the same type. For example, without departing from the scope of this document, the information labeled “first” could also be referred to as “second” information, and similarly, the “second” information could be referred to as “first.” Depending on the context, the singular forms “a”, “an” and “said/the” are intended to include the plural forms, unless the context indicates otherwise.

It should be understood that terms such as “top,” “bottom,” “up,” “down,” “vertical,” and “horizontal” as used herein indicate orientations or positional relationships based on the orientations or positional relationships shown in the drawings. These terms are used solely for ease of description of the application and for simplified description, and are not intended to indicate or imply that the referenced device must have a specific orientation, be constructed and operated with a specific orientation, and therefore should not be understood as a limitation on the present disclosure.

For ease of description, the following embodiments are described by way of example using an orthogonal coordinate system formed by a horizontal plane and a vertical direction. This premise should not be understood as a limitation on the present disclosure.

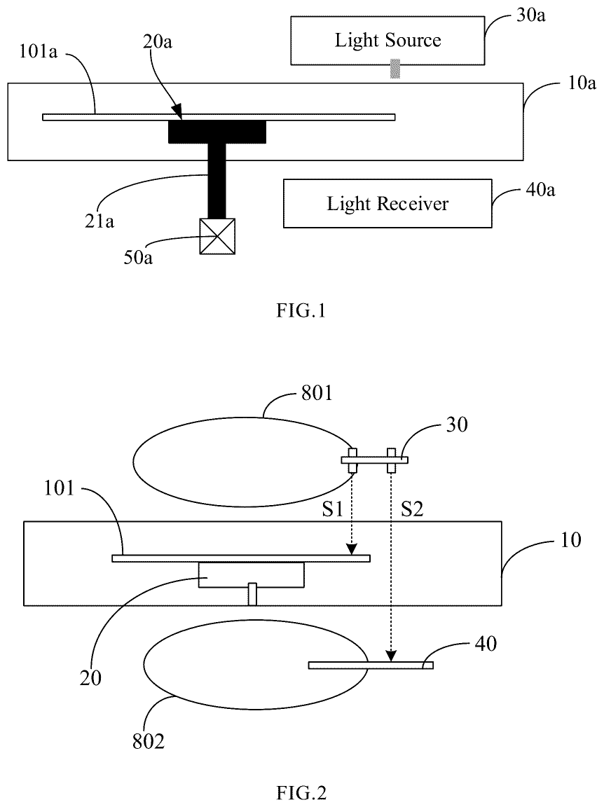

A wafer position detection device in the related art is shown in FIG. 1, which includes transparent windows for the detection light signals in the process chamber 10a, a rotating platform 20a, a light source 30a, a light receiver 40a, and a driving source 50a. The rotating platform 20a is located inside the process chamber 10a and is driven by the external driving source 50a to rotate. The rotating platform 20a is used to fix a wafer 101a and drive the wafer 101a to rotate. The light source 30a and the light receiver 40a are located on the upper and lower sides of the process chamber 10a respectively. The light source 30a projects a shadow of the wafer 101a to the light receiver 40a, and the light receiver 40a determines edge information of the wafer 101a (e.g., edge image information), and calculates the center of the wafer 101a based on the edge information.

Since the rotating platform 20a and the driving source 50a are located inside and outside the process chamber 10a respectively, the connecting moving parts between the rotating shaft 21a of the rotating platform 20a and the process chamber 10a requires sealing treatment. Moreover, for high-temperature wafer transfer, the temperature of the wafer 101a can reach above 800° C., which will cause the temperature of the process chamber 10a to be higher than 70° C. Consequently, a dedicated water-cooling device is required, which increases the overall complexity and maintenance difficulty of the equipment.

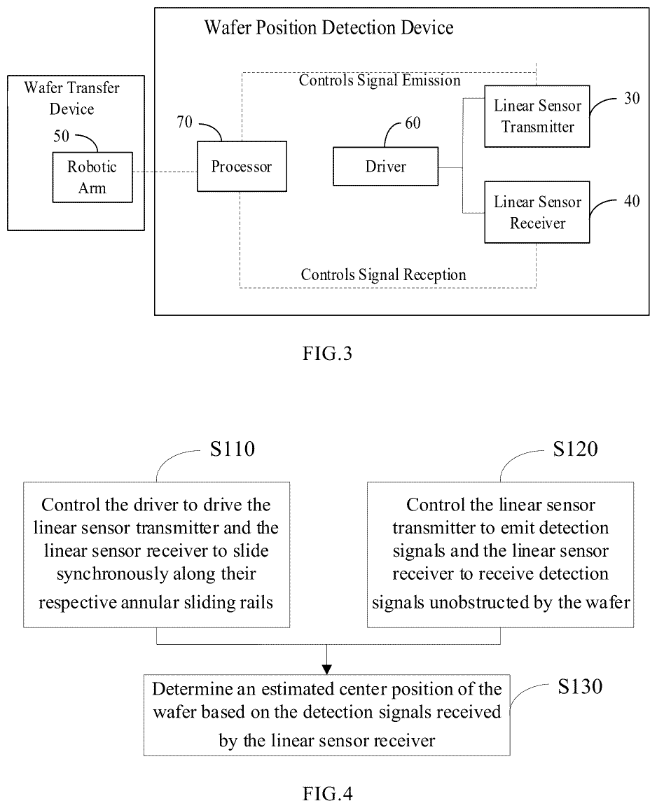

To solve the above technical problems, FIG. 2 and FIG. 3 disclose a structure and a system. FIG. 2 is a structural schematic diagram of a wafer position detection device according to an embodiment of the present disclosure, and FIG. 3 is a structural schematic diagram of a control system of the wafer position detection device according to an embodiment of the present disclosure. The wafer position detection device, applied to a semiconductor chamber 10, is used to detect the position of a wafer 101 in the semiconductor chamber 10, where the wafer 101 is located on a supporting portion 20 in the semiconductor chamber 10. The wafer position detection device may include: a first annular sliding rail 801, a second annular sliding rail 802, a linear sensor transmitter 30, a linear sensor receiver 40, a driver 60, and a processor 70.

The first annular sliding rail 801 and the second annular sliding rail 802 are oppositely arranged on the upper and lower sides of the semiconductor chamber 10. For example, the first annular sliding rail 801 may be located above the semiconductor chamber 10, and correspondingly, the second annular sliding rail 802 is located below the semiconductor chamber 10. Alternatively, the first annular sliding rail 801 may be located below the semiconductor chamber 10, and correspondingly, the second annular sliding rail 802 is located above the semiconductor chamber 10.

The linear sensor transmitter 30 is slidably connected to the first annular sliding rail 801, and the linear sensor receiver 40 is slidably connected to the second annular sliding rail 802; In addition, the orthogonal projection of the linear sensor transmitter 30 toward the wafer 101 and the orthogonal projection of the linear sensor receiver 40 toward the wafer 101 overlap with each other partially on the wafer 101. It is understandable that the radius of the first annular sliding rail 801 and the radius of the second annular sliding rail 802 can be designed according to the size of the wafer 101.

The driver 60 is used to drive the linear sensor transmitter 30 and the linear sensor receiver 40 to slide along their respective annular sliding rails.

The processor 70 is configured to: control the driver 60 to drive the linear sensor transmitter 30 and the linear sensor receiver 40 to slide synchronously along their respective annular sliding rails; and control the linear sensor transmitter 30 to emit detection signals and the linear sensor receiver 40 to receive detection signals unobstructed by the wafer 101. The processor 70 is further configured to determine the center position of the wafer 101 based on the detection signals received by the linear sensor receiver 40. The semiconductor chamber 10 has windows that are penetrable by the detection signals.

As an example, the driver 60 may include one driving source, which drives the linear sensor transmitter 30 and the linear sensor receiver 40 to slide synchronously along their respective annular sliding rails. As another example, the driver 60 may include two driving sources, and the two driving sources may respectively drive the linear sensor transmitter 30 and the linear sensor receiver 40 to slide along their respective annular sliding rails; in this case, the two driving sources can realize the synchronous sliding of the linear sensor transmitter 30 and the linear sensor receiver 40 along their respective annular sliding rails under the control of the processor 70. In addition, when it is necessary to adjust the relative position between the linear sensor transmitter 30 and the linear sensor receiver 40, each driving source can also, under the control of the processor 70, independently drive the linear sensor transmitter 30 or the linear sensor receiver 40 to slide along the respective annular sliding rail. By arranging two driving sources, the relative position between the linear sensor transmitter 30 and the linear sensor receiver 40 can be adjusted. This not only reduces the installation accuracy requirement for the relative position of the linear sensor transmitter 30 and the linear sensor receiver 40, but also ensures that the signals emitted by the linear sensor transmitter 30 can reach the linear sensor receiver 40 when they are not blocked by the wafer.

It should be noted that the linear sensor transmitter 30 and the linear sensor receiver 40 are two components of a one-dimensional sensor (linear sensor), which together form a through-beam sensor. The linear sensor transmitter 30 can emit detection signals over a certain one-dimensional length; that is, the detection signals have a certain length along a specified linear direction, and this length extends, for example, along a radial direction of the supporting portion. In FIG. 2, two exemplary arrows are used to indicate different detection beams (S1 and S2) emitted by the linear sensor transmitter 30, wherein emission positions of the detection signals span across the one-dimensional length. Some of the detection signals are blocked by the wafer 101 and others are not. When not blocked by the wafer 101, the detection signals emitted by the linear sensor transmitter 30 can penetrate the windows in the semiconductor chamber 10 and be received by the linear sensor receiver 40. As an example, the linear sensor transmitter 30 may be a line of light emitters (a one-dimensional light source), such as a line light source formed by arranging a plurality of LEDs or laser emitters in a straight line. Laser is preferred as an example; compared with LEDs, lasers are less susceptible to interference from ambient light.

The line light source may emit optical signals to the linear sensor receiver 40. The bottom window and top window of the semiconductor chamber 10 may be made of transparent materials (such as quartz) to allow the optical signals to pass through. The linear sensor receiver 40 may include a plurality of sensors arranged in a straight line, and each sensor may receive the aforementioned signals. Such sensors may be light detectors, for example, Charge-coupled Device (CCD) detectors. To reduce the installation accuracy requirement for the relative position between the linear sensor transmitter 30 and the linear sensor receiver 40, and to ensure that the signals emitted by the linear sensor transmitter 30 can be projected onto the linear sensor receiver 40 when not blocked by the wafer, the length of the linear sensor receiver 40 may be greater than that of the linear sensor transmitter 30.

In addition, according to wafers of different sizes, the installation position of the linear sensor transmitter 30 can be configured such that a part of the emitted detection signals (signal S1) is blocked by the wafer 101, and the other part (signal S2) penetrates the transparent windows of the semiconductor chamber 10 while approaching the edge of the wafer 101 and is received by the linear sensor receiver 40. When the linear sensor transmitter 30 and the linear sensor receiver 40 move synchronously for one full circle, a full scan of the edge of the wafer 101 can be completed.

As an example, FIG. 4 is a schematic diagram of a control flow of a semiconductor processor according to an embodiment of the present disclosure. The processor 70 can detect the center position of the wafer 101 by executing steps S110 to S130.
S110: controlling the driver to drive the linear sensor transmitter and the linear sensor receiver to slide synchronously along their respective annular sliding rails.
S120: controlling the linear sensor transmitter to emit detection signals and the linear sensor receiver to receive detection signals unobstructed by the wafer.
S130: determining the estimated center position of the wafer based on the detection signals received by the linear sensor receiver.

As described above, the wafer position detection device comprises a linear sensor transmitter 30 and a linear sensor receiver 40, forming a pair of opposing sensors positioned on opposite sides of the wafer 101 sitting inside process chamber—above and below from outside of the process chamber. The projection of the linear sensor transmitter 30 onto the wafer 101 from one side, and the projection of the linear sensor receiver 40 onto the wafer 101 from the opposing side, partially overlap with each other on the wafer 101 from the top and bottom two sides. This allows for the identification of the edge of the wafer 101. The processor 70 controls the driver 60 to synchronously slide the linear sensor transmitter 30 and the linear sensor receiver 40 along their respective annular rails (801, 802), enabling a scan of the entire wafer 101 circumference to determine the center position of the wafer 101. The presently disclosed wafer position detection device avoids the need for sealing the connecting moving parts between a rotation shaft and the semiconductor chamber, a problem present in existing detection devices, because the wafer 101 herein is fixed and stationary within the semiconductor chamber 10. Because the components connected to the semiconductor chamber 10 do not include a moving motor, a cooling system is also unnecessary, even when used for high-temperature wafer handling. This simplifies the system and reduces maintenance difficulty.

Steps S110 and S120 may be executed simultaneously to enable scanning of the entire edge of the wafer 101.

As an example, after step S130, the processor 70 may also be configured to execute step S140.
S140: comparing the estimated center position of the wafer with a pre-stored target position, and determining an offset between the center position of the wafer and the target position.

After calculating the center position of the wafer, the determined center position of the wafer can be compared with the pre-stored target position to determine the offset between the center position of the wafer and the target position. In this way, when the center position deviates from the target position, the subsequent wafer transfer process can calibrate the center position to the target position.

As an example, FIG. 5 is a flowchart illustrating a method for determining a center position of a wafer according to an embodiment of the present disclosure. S130 may include S131 and S132:
S131: determining the estimated center position of the wafer based on the detection signals received by the linear sensor receiver 40.

For example, in the area blocked by the wafer 101, the linear sensor receiver 40 does not receive signals, and this area can be fed back as Area 0; in the area not blocked by the wafer 101, the linear sensor receiver 40 can receive signals, and this area can be fed back as Area 1. The boundary between Areas 1 and 0 can be determined as an edge of the wafer 101. After the linear sensor transmitter 30 and the linear sensor receiver 40 move synchronously to scan the edge of the wafer 101 for a full circle, the contour of the wafer 101 can be obtained.

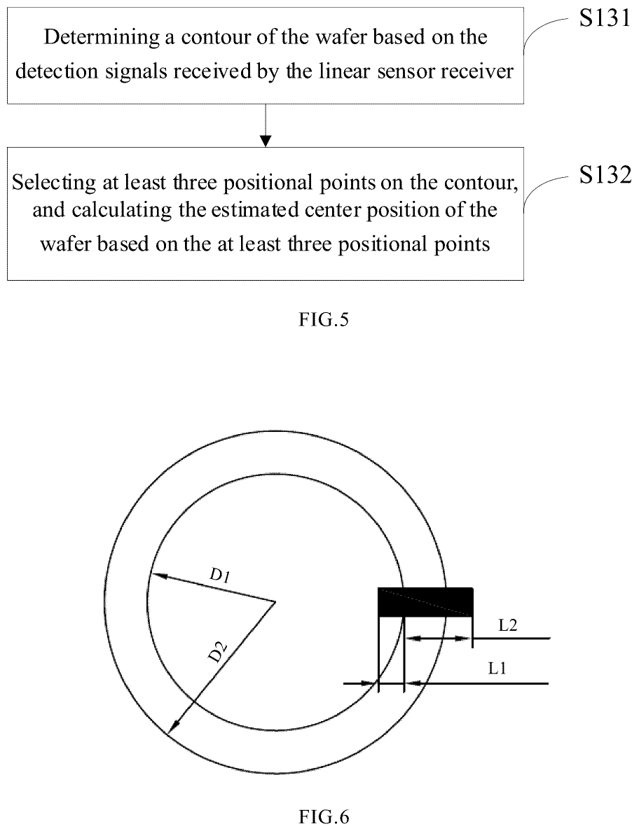

As an example, please refer to FIG. 6, which is a schematic diagram showing projections of a linear sensor transmitter and linear sensor receiver onto the wafer according to an embodiment of the present disclosure. When the wafer position detection device needs to be compatible with the contour recognition of wafers each having diameter of 6 inches (radius D1=75 mm) and 8 inches (radius D2=100 mm), linear sensors (including the linear sensor transmitter 30 and linear sensor receiver 40) with a length of 55 mm can be used.

Taking a 6-inch diameter wafer as an example, the projection of the linear sensor on the 6-inch wafer has an inside length L1=15 mm that overlaps with the 6-inch wafer, and an outside length L2=40 mm that extends beyond the edge of the 6-inch wafer. When switching to an 8-inch wafer, the projection of the linear sensor on the 8-inch wafer has an inside length of 40 mm that overlaps with the 8-inch wafer and an outside length of 15 mm that extends beyond the edge of the 8-inch wafer. This ensures that the linear sensors can perform edge scanning and recognition on wafers of two sizes (6 inches and 8 inches) to determine the contour of the wafer.

Of course, if necessary, the length of the linear sensors can be further increased, or the radial position of the linear sensors along the wafer can be adjusted to adapt to wafers of larger sizes.

To reduce the amount of data processing, the processor 70 may control the linear sensor receiver 40 to perform a detection signal reception each time it moves a predetermined arc length when performing a synchronous circular motion, wherein the predetermined arc length is less than a predetermined calibration accuracy.

That is, on the premise of meeting the calibration accuracy, the amount of data processing is reduced. Taking an 8-inch wafer (with a circumference of 628 mm) and a calibration accuracy of 0.1 mm as an example, 8192 points can be taken (detection-signal receptions can be performed 8192 times by rule) during the process of scanning one circle. Then the predetermined arc length is 628/8192=0.077 mm, which is less than 0.1 mm, so that the calibration accuracy requirement can be met. The coordinates of the 8192 points on the edge of the wafer can be recorded in sequence as (X₁, Y₁), (X₂, Y₂), . . . , (X₈₁₉₂, Y₈₁₉₂).

To meet the requirement for the wafer edge recognition accuracy (calibration accuracy), as an example, the linear sensor transmitter 30 extends along a radius of the first annular sliding rail 801, and the linear sensor transmitter 30 comprises signal emitting spots spaced apart by a predetermined distance. The linear sensor receiver 40 extends along a radius of the second annular sliding rail 802 and the linear sensor receiver comprises signal receiving spots spaced apart by the predetermined distance, wherein the signal receiving spots align one-to-one with the signal emitting spots and form a through-beam arrangement. Herein, the predetermined distance is less than a predetermined calibration accuracy. For instance, taking the total length of the linear sensor receiver 40 as 55 (40 mm+15 mm) mm and the calibration accuracy as 0.1 mm as an example, at least 550 signal receiving spots can be arranged on the linear sensor receiver 40, so that the distance between two adjacent signal receiving spots is 0.1 mm, thereby meeting the requirement for the wafer edge recognition accuracy.
S132, selecting at least three positional points on the contour, and calculating the center position of the wafer based on the at least three positional points.

For example, at the boundary between the aforementioned Areas 1 and 0, three positional points corresponding to Area 1 may be selected to calculate the center position of the wafer. Three non-collinear points can define a circle.

Several additional positional points corresponding to Area 1 may also be selected to verify the calculation result; similarly, three positional points corresponding to Area 0 may also be selected at the aforementioned boundary to calculate the center position of the wafer, and the midpoint of the two center positions may also be used as the estimated center position to reduce calculation errors.

Since a wafer is generally provided with an orientation feature (a flat or a notch, e.g., a V-shaped notch), that is, the contour of the wafer is not a complete circle. When three positional points are randomly selected on the recognized contour, there is a possibility that one or more of the selected points are located at the orientation feature, which may result in a large error in the calculation of the center position of the wafer.

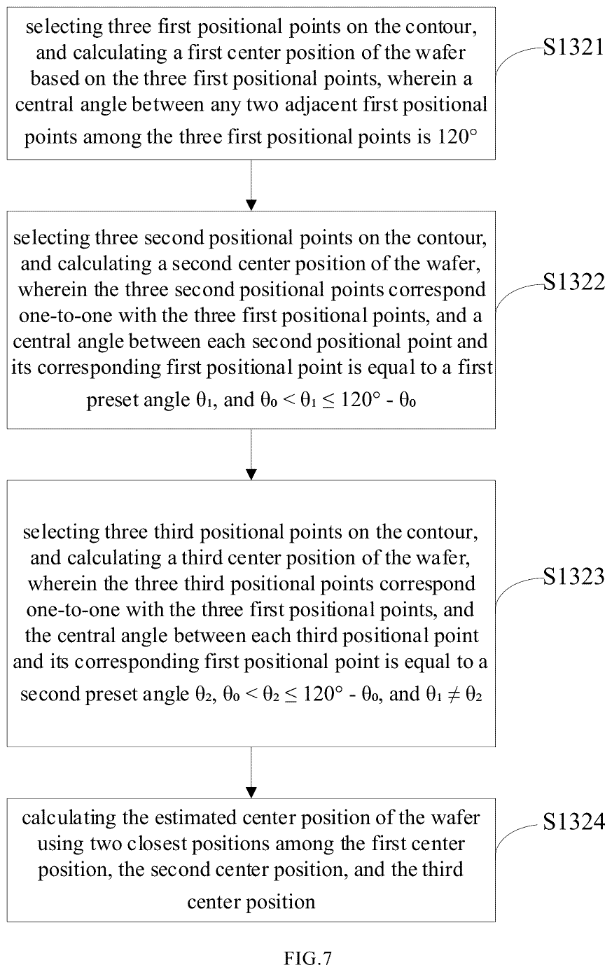

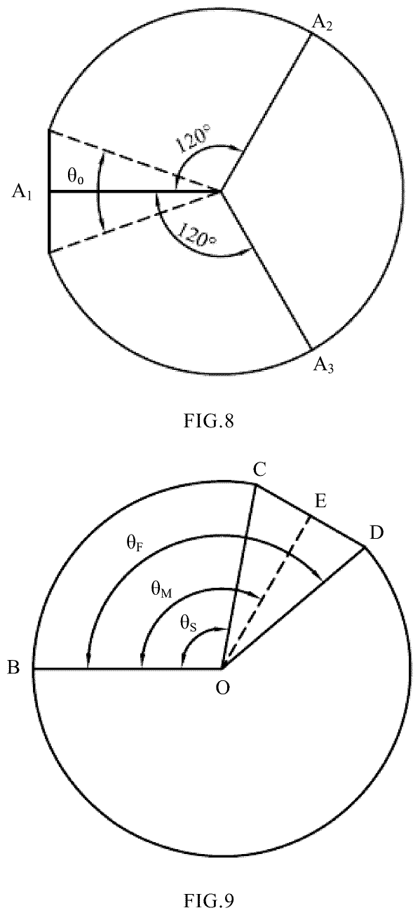

As a preferred example, please refer to FIG. 7, which is a schematic flowchart of a preferred method for calculating the center position according to an embodiment of the present disclosure. Taking the central angle spanned over the orientation feature as θ₀ as an example, the method for calculating the center position in step S132 may include:
S1321: selecting three first positional points on the contour, and calculating a first center position of the wafer (e.g., based on the three first positional points), wherein a first central angle between any two adjacent first positional points among the three first positional points is 120°.

Refer to FIG. 8, which is a schematic diagram illustrating the selection of three position points on a contour of a wafer according to an embodiment of the present disclosure. It is understandable that the first positional points are selected every 120° on the contour, and the first center position can be calculated based on the three first positional points. Taking points at the positions of 0°, 120°, and 240° respectively, the coordinates of the three first positional points are A₁ ((X¹₁, Y¹₁), A₂ (X¹₂, Y¹₂), and A₃ (X¹₃, Y¹₃) respectively; the coordinate of the corresponding first center position A¹₀ is (X¹₀, Y¹₀). The coordinate of the first center position A₀ can be calculated according to the following equations (1) to (3).

$${( {X}_{1}^{1} - {X}_{0}^{1} )}^{2} + {( {Y}_{1}^{1} - {Y}_{0}^{1} )}^{2} = {R}^{2} \qquad ( 1 )$$

$${( {X}_{2}^{1} - {X}_{0}^{1} )}^{2} + {( {Y}_{2}^{1} - {Y}_{0}^{1} )}^{2} = {R}^{2} \qquad ( 2 )$$

$${( {X}_{3}^{1} - {X}_{0}^{1} )}^{2} + {( {Y}_{3}^{1} - {Y}_{0}^{1} )}^{2} = {R}^{2} \qquad ( 3 )$$

S1322: selecting three second positional points on the contour, and calculating a second center position of the wafer, wherein the three second positional points correspond one-to-one with the three first positional points, and a second central angle between each second positional point and its corresponding first positional point is equal to a first preset angle θ₁, and θ₀<θ₁≤120°−θ₀.

It is understandable that the three second positional points are equivalent to points selected after rotating the three first positional points by a certain angle θ₁. Since the notch or flat cut on a wafer spans an angle of θ₀, which is generally less than 2°, θ₁ usually only needs to be greater than 2° and less than 118°. For example, if the first preset angle θ₁ is 45°, it is equivalent to selecting three second positional points from the corresponding positions on the contour after rotating the first positional point A1 (serving as the origin, at the 0° position) by 45°, 165°, and 285°.

Based on the three second positional points, the coordinate of the second center position A²₀ of the wafer can be calculated as (X²₀, Y²₀). Refer to the content above for the specific calculation method.
S1323: selecting three third positional points on the contour, and calculating a third center position of the wafer, wherein the three third positional points correspond one-to-one with the three first positional points, and the third central angle between each third positional point and its corresponding first positional point is equal to a second preset angle θ₂, θ₀<θ₂≤120°−θ₀, and θ₁≠θ₂.

For the specific embodiment of step S1323, reference may be made to the embodiment of step S1322, except that the second preset angle θ₂ has a different value. For example, θ₂ may be 90°. Three third positional points are selected from the corresponding positions on the contour after rotating the first positional point A1 (serving as the origin, at the 0° position) by 90°, 210°, and 330°, and the coordinate of the third center position A³₀ of the wafer is calculated as (X³₀, Y³₀).
S1324: calculating the estimated center position of the wafer by averaging two closest positions among the first center position, the second center position, and the third center position of the wafers.

For the three center positions, since the angle θ₁ (by which the positional points are rotated on the wafer in the second calculation) and the angle θ₂ (by which the positional points are rotated on the wafer too in the third calculation) satisfy θ₀<(θ₁, θ₂)≤120°−θ₀ and θ₁≠θ₂, it can be ensured that among the positional points selected during the three selections, the positional points selected during at least two selections can avoid falling at the orientation feature of the wafer. This allows the acquired two center positions substantially coincident, and the estimated center position of the wafer can be determined by using these two center positions.

As shown, the distances between every two of the first center position, the second center position, and the third center position can be calculated, and the estimated center position of the wafer can be determined by averaging the two positions with the smallest distance. For example, when the distance between the first center position and the second center position is the smallest, the first center position may be used as the center position of the wafer, the second center position may be used as the center position of the wafer, or the midpoint between the first center position and the second center position may be used as the estimated center position of the wafer. The method of calculating the center position three times adopted herein can avoid excessive errors in the calculation of the center position of the wafer.

As an example, the processor is further configured to perform S133.
S133: calculate an azimuth angle of the orientation feature relative to the estimated center position of the wafer.

Taking the flat edge on a wafer as a type of orientation feature as an example, the intersection point between the axis of symmetry of the orientation feature and the contour is used as the reference position for calculating the azimuth angle of the orientation feature. Please refer to FIG. 9, which is a schematic diagram illustrating the detection of the azimuth angle of the orientation feature on the wafer according to an embodiment of the present disclosure. For the flat feature at the edge of the wafer in FIG. 9, the reference position of the orientation feature is Point E, and the azimuth angle of the orientation feature relative to the center position is θ_{M}.

θ_{M} may be calculated based on the recognized contour.

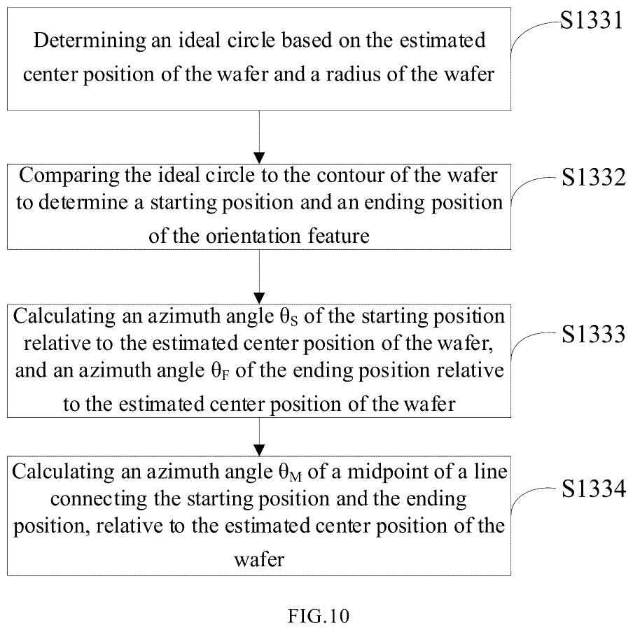

FIG. 10 is a flowchart illustrating a process for calculating the azimuth angle of the orientation feature relative to the estimated center position of the wafer according to an embodiment of the present disclosure. Step S133 may include S1331-S1334.
S1331: determining an ideal circle based on the estimated center position of the wafer and a radius of the wafer.

Since the radius of the wafer is known and the estimated center position of the wafer has been calculated, the ideal circle corresponding to the wafer can be determined. The ideal circle is a complete circle (without the wafer's orientation feature) corresponding to the contour. Based on the estimated center position and the radius of the wafer, the arc spanned over the orientation feature can be restored, and the coordinate data M0 of the entire ideal circle can be obtained.
S1332: comparing the ideal circle to the contour of the wafer to determine a starting position and an ending position of the orientation feature.

For example, a logical “AND” operation may be performed between the coordinate data M₀ of the ideal circle and the coordinate data M1 of the contour (with the boundary regarded as “1”). The starting position and ending position of the orientation feature are determined based on the result of the operation. Take the clockwise operation as an example.

At Position C, due to the presence of the orientation feature, the result of the “AND” operation changes from 1 to 0, so Position C can be determined as the starting position (X_{1c}, Y_{1c}) of the orientation feature.

At Position D, due to the presence of the orientation feature, the result of the “AND” operation changes from 0 to 1, so Position D can be determined as the ending position (X_{1d}, Y_{1d}) of the orientation feature.
S1333: calculating an azimuth angle θ_{S} of the starting position relative to the estimated center position of the wafer, and an azimuth angle θ_{F} of the ending position relative to the estimated center position of the wafer.

Taking the azimuth angle of position B in FIG. 9 relative to the center O being 0° as an example, the azimuth angles θ_{S} and θ_{F} of the starting position C and the ending position D relative to the center O can be calculated respectively based on their coordinates.
S1334: calculating an azimuth angle θ_{M} of a midpoint of a line connecting the starting position and the ending position, relative to the estimated center position of the wafer.

Specifically, the azimuth angle of Point E (the midpoint of the line connecting the starting position C and the ending position D) relative to the estimated center position is: θ_{M}=(θ_{S}+∂4_{F})/2.

Determining the azimuth angle of the wafer's orientation feature facilitates accurate wafer transfer in subsequent processes.

The present disclosure further provides a semiconductor equipment, including a semiconductor chamber 10, a wafer transfer device, and a wafer position detection device described above. The wafer position detection device is configured to detect a position of a wafer located within the semiconductor chamber 10; the wafer transfer device is configured to transfer the wafer and perform position correction on the wafer based on detection results from the wafer position detection device.

Refer to FIG. 2 and FIG. 3. The wafer transfer device may include a robotic arm 50, and the processor 70 may control the robotic arm 50 to pick up the wafer 101 from the supporting portion 20 of the semiconductor chamber 10.

In one embodiment, when the estimated center position of the wafer calculated by the processor 70 deviates from the pre-stored target position by more than a preset position threshold, the processor 70 may control the robotic arm 50 to calibrate the center position to the target position. For example, the robotic arm may adjust the position of the wafer 101 in the X direction and Y direction within the XY horizontal plane.

As an example, when the azimuth angle of the orientation feature relative to the center position (calculated by the processor 70) deviates from a target angle by more than a preset angle threshold, the processor 70 may control the robotic arm 50 to calibrate the azimuth angle of the orientation feature to the target angle. For example, when the target angle of the orientation feature is 0° (refer to FIG. 8), the robotic arm 50 may be controlled to rotate the wafer by −θ_{M} (i.e., rotate counterclockwise by θ_{M}), thereby completing the calibration of the azimuth angle of the orientation feature. That is, in addition to performing translational operations on the wafer to calibrate the center position, the robotic arm 50 may also perform rotational operations to calibrate the angle of the orientation feature.

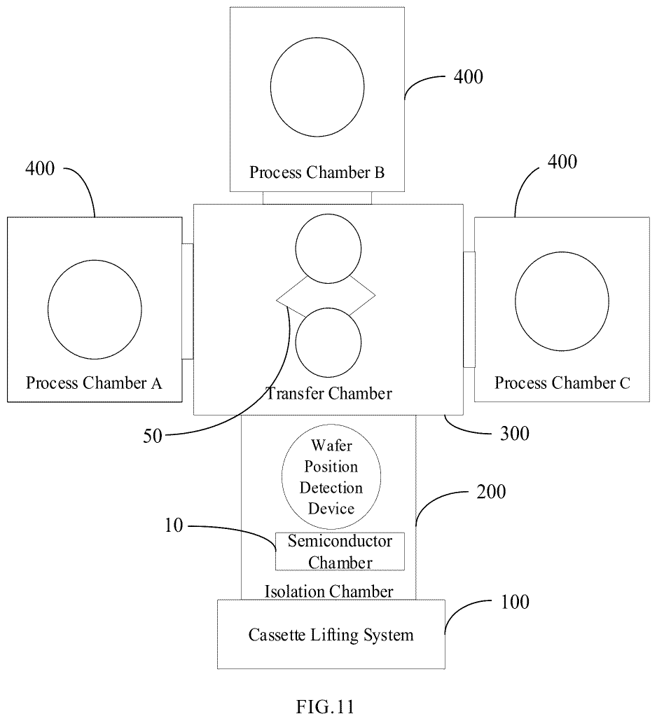

FIG. 11 is a schematic diagram of an application scenario of the semiconductor device according to an embodiment of the present disclosure, including a cassette lifting system 100, an isolation chamber 200, a transfer chamber 300, and process chambers 400. The semiconductor chamber 10 and the wafer position detection device described in the above embodiments are arranged in the isolation chamber 200.

The cassette lifting system 100 is used to transport wafer cassettes loaded with wafers, and can transport the wafers in the wafer cassettes to the semiconductor chamber 10 through a robotic arm, and the wafer position detection device detects the position and angle of the wafers; the robotic arm 50 in the transfer chamber 300 can pick up wafers from the semiconductor chamber 10, calibrate the position and angle of the wafers according to the detection results of the wafer position detection device, and sequentially transport them to the transfer chamber 300 and the process chambers 400. Note that, multiple process chambers 400 may be arranged around the transfer chamber 300 to improve efficiency.

Regarding other operating principles and processes of the semiconductor device, please refer to the description of the wafer position detection device in the aforementioned embodiments of the present disclosure.

The above provides a detailed description of a wafer position detection device and a semiconductor equipment according to the present disclosure, and the principles and implementation methods of the present disclosure are described using specific examples in this document. It should be noted that the descriptions of the various embodiments in the present disclosure each have their own focus. Parts not described or recorded in detail in one embodiment can be referenced in the relevant descriptions of other embodiments.

The technical features of the technical solution of the present disclosure can be combined in any way. In order to keep the description concise, not all possible combinations of the technical features in the above embodiments have been described. However, as long as there is no contradiction in the combination of these technical features, they should all be considered within the scope of the present disclosure.

1. A wafer position detection device, applied to a semiconductor chamber, the wafer position detection device comprising:
a first annular sliding rail, a second annular sliding rail, a linear sensor transmitter, a linear sensor receiver, a driver, and a processor;
wherein the semiconductor chamber is provided with a supporting portion for carrying a wafer;
wherein the wafer position detection device is disposed outside the semiconductor chamber;
wherein the first annular sliding rail and the second annular sliding rail are oppositely arranged on upper and lower sides of the semiconductor chamber;
wherein the linear sensor transmitter slides on the first annular sliding rail, and the linear sensor receiver slides on the second annular sliding rail;
wherein an orthogonal projection of the linear sensor transmitter toward the wafer and an orthogonal projection of the linear sensor receiver toward the wafer overlap with each other partially on the wafer;
wherein the driver is configured to drive the linear sensor transmitter to slide along the first annular sliding rail, and the linear sensor receiver to slide along the second annular sliding rail;
wherein the processor is configured to perform steps of:
S110, control the driver to drive the linear sensor transmitter and the linear sensor receiver to slide synchronously along their respective annular sliding rails;
S120, control the linear sensor transmitter to emit detection signals and the linear sensor receiver to receive detection signals unobstructed by the wafer;
S130, determine an estimated center position of the wafer based on the detection signals received by the linear sensor receiver; and
wherein the semiconductor chamber comprises windows penetrable to the detection signals.

2. The wafer position detection device according to claim 1, wherein S130 further comprises:
S131, determining a contour of the wafer based on the detection signals received by the linear sensor receiver; and
S132, selecting at least three positional points on the contour, and calculating the estimated center position of the wafer based on the at least three positional points.

3. The wafer position detection device according to claim 2, wherein an orientation feature is provided on an edge of the wafer, and an orientation-feature-central angle spanned over the orientation feature is θ₀, wherein S132 further comprises:
S1321, selecting three first positional points on the contour, and calculating a first center position of the wafer based on the three first positional points, wherein a first central angle between any two adjacent first positional points among the three first positional points is 120°;
S1322, selecting three second positional points on the contour, and calculating a second center position of the wafer, wherein the three second positional points correspond one-to-one with the three first positional points, and a second central angle between each second positional point and its corresponding first positional point is equal to a first preset angle θ₁, and θ₀<θ₁≤120°−θ₀;
S1323, selecting three third positional points on the contour, and calculating a third center position of the wafer, wherein the three third positional points correspond one-to-one with the three first positional points, and a third central angle between each third positional point and its corresponding first positional point is equal to a second preset angle θ₂, θ₀<θ₂≤120°−θ₀, and θ₁≠θ₂; and
S1324, calculating the estimated center position of the wafer by averaging two closest positions among the first center position, the second center position, and the third center position of the wafer.

4. The wafer position detection device according to claim 2, wherein an orientation feature is provided on an edge of the wafer, and wherein the processor is further configured to perform a step of:
S133, calculating an azimuth angle of the orientation feature relative to the estimated center position of the wafer.

5. The wafer position detection device according to claim 4, wherein S133 further comprises:
S1331, determining an ideal circle based on the estimated center position of the wafer and a radius of the wafer;
S1332, comparing the ideal circle to the contour of the wafer to determine a starting position and an ending position of the orientation feature;
S1333, calculating an azimuth angle θ_{S} of the starting position relative to the estimated center position of the wafer, and an azimuth angle θ_{F} of the ending position relative to the estimated center position of the wafer;
S1334, calculating an azimuth angle θ_{M} of a midpoint of a line connecting the starting position and the ending position, relative to the estimated center position of the wafer.

6. The wafer position detection device according to claim 1, wherein the processor is further configured to compare the estimated center position of the wafer with a pre-stored target position, and determine an offset between the estimated center position of the wafer and the target position.

7. The wafer position detection device according to claim 1, wherein controlling the linear sensor receiver to receive the detection signals unobstructed by the wafer comprises:
controlling the linear sensor receiver to perform a detection signal reception each time it slides a predetermined arc length along the second annular sliding rail, wherein the predetermined arc length is less than a predetermined calibration accuracy.

8. The wafer position detection device according to claim 7, wherein the linear sensor transmitter extends along a radius of the first annular sliding rail, and wherein the linear sensor transmitter comprises signal emitting spots spaced apart by a predetermined distance;
wherein the linear sensor receiver extends along a radius of the second annular sliding rail, and wherein the linear sensor receiver comprises signal receiving spots spaced apart by the predetermined distance, wherein the signal receiving spots align one-to-one with the signal emitting spots, and wherein the predetermined distance is less than the predetermined calibration accuracy.

9. The wafer position detection device according to claim 1, wherein the linear sensor transmitter comprises a line of light emitters; and
wherein the linear sensor receiver comprises a line of light detectors.

10. A semiconductor equipment, comprising a semiconductor chamber, a wafer transfer device, and a wafer position detection device;
wherein the wafer position detection device is configured to detect a position of a wafer located within the semiconductor chamber;
wherein the wafer position detection device comprises a first annular sliding rail, a second annular sliding rail, a linear sensor transmitter, a linear sensor receiver, a driver, and a processor;
wherein the semiconductor chamber is provided with a supporting portion for carrying the wafer;
wherein the wafer position detection device is disposed outside the semiconductor chamber;
wherein the first annular sliding rail and the second annular sliding rail are oppositely arranged on upper and lower sides of the semiconductor chamber;
wherein the linear sensor transmitter slides on the first annular sliding rail, and the linear sensor receiver slides on the second annular sliding rail;
wherein an orthogonal projection of the linear sensor transmitter toward the wafer and an orthogonal projection of the linear sensor receiver toward the wafer overlap with each other partially on the wafer;
wherein the driver is configured to drive the linear sensor transmitter to slide along the first annular sliding rail, and the linear sensor receiver to slide along the second annular sliding rail;
wherein the processor is configured to perform steps of:
S110, control the driver to drive the linear sensor transmitter and the linear sensor receiver to slide synchronously along their respective annular sliding rails;
S120, control the linear sensor transmitter to emit detection signals and the linear sensor receiver to receive detection signals unobstructed by the wafer;
S130, determine an estimated center position of the wafer based on the detection signals received by the linear sensor receiver; and
wherein the semiconductor chamber comprises windows penetrable to the detection signals; and
wherein the wafer transfer device is configured to transfer the wafer and perform position correction on the wafer based on detection results from the wafer position detection device.

11. The semiconductor equipment according to claim 10, wherein S130 further comprises:
S131, determining a contour of the wafer based on the detection signals received by the linear sensor receiver; and
S132, selecting at least three positional points on the contour, and calculating the estimated center position of the wafer based on the at least three positional points.

12. The semiconductor equipment according to claim 11, wherein an orientation feature is provided on an edge of the wafer, and an orientation-feature-central angle spanned over the orientation feature is θ₀, wherein S132 further comprises:
S1321, selecting three first positional points on the contour, and calculating a first center position of the wafer based on the three first positional points, wherein a first central angle between any two adjacent first positional points among the three first positional points is 120°;
S1322, selecting three second positional points on the contour, and calculating a second center position of the wafer, wherein the three second positional points correspond one-to-one with the three first positional points, and a second central angle between each second positional point and its corresponding first positional point is equal to a first preset angle θ₁, and θ₁≤θ₁≤120°−θ₀;
S1323, selecting three third positional points on the contour, and calculating a third center position of the wafer, wherein the three third positional points correspond one-to-one with the three first positional points, and a third central angle between each third positional point and its corresponding first positional point is equal to a second preset angle θ₂, θ₀<θ₂≤120°−θ₀, and θ₁≠θ₂; and
S1324, calculating the estimated center position of the wafer by averaging two closest positions among the first center position, the second center position, and the third center position of the wafer.

13. The semiconductor equipment according to claim 11, wherein an orientation feature is provided on an edge of the wafer, and wherein the processor is further configured to perform a step of:
S133, calculating an azimuth angle of the orientation feature relative to the estimated center position of the wafer.

14. The semiconductor equipment according to claim 13, wherein S133 further comprises:
S1331, determining an ideal circle based on the estimated center position of the wafer and a radius of the wafer;
S1332, comparing the ideal circle to the contour of the wafer to determine a starting position and an ending position of the orientation feature;
S1333, calculating an azimuth angle θ_{S} of the starting position relative to the estimated center position of the wafer, and an azimuth angle θ_{F} of the ending position relative to the estimated center position of the wafer;
S1334, calculating an azimuth angle θ_{M} of a midpoint of a line connecting the starting position and the ending position, relative to the estimated center position of the wafer.

15. The semiconductor equipment according to claim 10, wherein the processor is further configured to compare the estimated center position of the wafer with a pre-stored target position, and determine an offset between the estimated center position of the wafer and the target position.

16. The semiconductor equipment according to claim 10, wherein controlling the linear sensor receiver to receive the detection signals unobstructed by the wafer comprises:
controlling the linear sensor receiver to perform a detection signal reception each time it slides a predetermined arc length along the second annular sliding rail, wherein the predetermined arc length is less than a predetermined calibration accuracy.

17. The semiconductor equipment according to claim 10, wherein the linear sensor transmitter extends along a radius of the first annular sliding rail, and wherein the linear sensor transmitter comprises signal emitting spots spaced apart by a predetermined distance;
wherein the linear sensor receiver extends along a radius of the second annular sliding rail, and wherein the linear sensor receiver comprises signal receiving spots spaced apart by the predetermined distance, wherein the signal receiving spots align one-to-one with the signal emitting spots, and wherein the predetermined distance is less than the predetermined calibration accuracy.

18. The semiconductor equipment according to claim 10, wherein the linear sensor transmitter comprises a line of light emitters; and
wherein the linear sensor receiver comprises a line of light detectors.
